(19) United States
(12) Patent Application Publication
(10) Pub. No.: US 2017/0166407 A1
(43) Pub. Date: Jun. 15, 2017

(54) UNIVERSAL PICK AND PLACE HEAD FOR HANDLING COMPONENTS OF ANY SHAPE

(71) Applicant: Intel Corporation, Santa Clara, CA (US)

(72) Inventors: Kumar Abhishek Singh, Phoenix, AZ (US); Pramod Malatkar, Chandler, AZ (US); Joshua D. Heppner, Chandler, AZ (US); Jimin Yao, Chandler, CA (US)

(21) Appl. No.: 14/969,707

(22) Filed: Dec. 15, 2015

(51) Int. Cl. B65G 47/91; H05K 13/04; B25J 15/06

(52) U.S. Cl. CPC B65G 47/91; B25J 15/0616; H05K 13/0408

(57) ABSTRACT

A pick and place machine includes a frame to adjustably mount, in three dimensions, a plurality of vacuum nozzles over a component to be picked according to a first embodiment a multi-head PnP mechanism may be simple and flexible to train for a wide variety of component and package shapes and sizes. Multiple PnP nozzles are staggered independently in three axes. According to a second embodiment, a PnP mechanism uses an array of self-learning nozzles that adapt by adjusting the z height of individual nozzles to the shape of the object to be picked.

### BACKGROUND

This relates to semiconductor packaging and particularly to pick and place mechanisms.

With the advent of new technologies like wearables and Internet of things, there is a growing need for assembly of non-Cartesian and irregular packages and components. In many cases these packages can be flexible (for example sensors on clothes) or odd-shaped (for example the system in package chips for a watch or smart glass).

A pick and place (PnP) mechanism is a robotic machine that places surface mount devices on a printed circuit board. They are used, for example, to make computers, consumer electronics, industrial, medical, automation and telecommunication equipment.

Existing pick and place mechanisms using a traditional single head (for single component) or gang type heads (for multiple components) are inadequate for these applications. Any capable PnP mechanism will not only need to provide flexibility for picking irregularly sized packages but also match traditional PnP mechanisms in terms of delicate handling of sensitive semiconductor packages and components. Additionally, to keep the cost down, these mechanisms need to be adaptive and robust for components of different shapes and sizes and maintain comparable throughput to that of the traditional systems.

Existing PnP mechanisms include single head PnP for small and planar surface components, multiple head (gang-like) PnP mechanisms, and robotic PnP mechanisms. The robotic PnP mechanism includes tactile fingers or single/multi pickup nozzles attached to robotic arms. These can be used for odd-shaped objects; however, they are not sensitive enough and not ideal for ultrathin or delicate packages. Also they have higher costs in terms of installation and slower throughput as well as requiring individual programming for different pick up scenarios.

The existing mechanisms involve a single head picking single small object at a time or multiple heads picking flat objects or similar multiple objects at a time. These mechanisms are unsuitable to be used for PnP of odd-shaped, non-planar components.

### BRIEF DESCRIPTION OF THE DRAWINGS

Some embodiments are described with respect to the following figures:

FIG. 1 is a side view of pickup head gang including four heads picking an odd-shaped object at the bottom of the figure, according to one embodiment;

FIG. 2 is a top view of the staggered positioning of the pickup head gang shown in FIG. 1;

FIG. 3 is a cross-sectional view of a locking mechanism for a pickup head using a screw bolt lock in accordance with one embodiment;

FIG. 4 is a cross-sectional view of a locking mechanism for a pickup head using a screw head lock according to one embodiment;

FIG. 5 is a side view of a pickup head with nozzle matrix picking an odd-shaped object at the bottom of the depiction according to one embodiment;

FIG. 6 is a top view of an odd-shaped object showing the nozzle contacting the object being picked according to one embodiment;

FIGS. 7A, 7B, and 7C are respectively front, tilted and side views of a component to be picked;

FIGS. 8A, 8B, and 8C are respectively front, tilted and side views of a PnP head in contact with the component shown in FIGS. 7A-7C in accordance with one embodiment;

FIG. 9 is a flow chart for one embodiment;

FIG. 10 is a cutaway view of a single nozzle with the outer sleeve cutaway but indicated in dashed lines according to one embodiment;

FIG. 11 is a side view of a matrix of nozzles in the unlocked position according to one embodiment;

FIG. 12 is a side view of a matrix of nozzles in the locked position in varying heights according to one embodiment;

FIG. 13 is an enlarged cutaway view of a nozzle in the locked position corresponding to FIG. 12 with the outer sleeve cutaway but indicated in dashed lines; and

FIG. 14 is a flow chart for one embodiment.

### DETAILED DESCRIPTION

According to a first embodiment a multi-head PnP mechanism may be simple and flexible to train for a wide variety of component and package shapes and sizes. Multiple PnP nozzles are staggered independently in three axes.

According to a second embodiment, a PnP mechanism uses an array of self-learning nozzles that adapt by adjusting the height of individual nozzles to the shape of the object to be picked.

A multi-head PnP mechanism allows for adaptive pick and place systems working in tandem to handle irregularly shaped objects. These systems may be integrated into materials handling systems of pre-existing semiconductor manufacturing equipment.

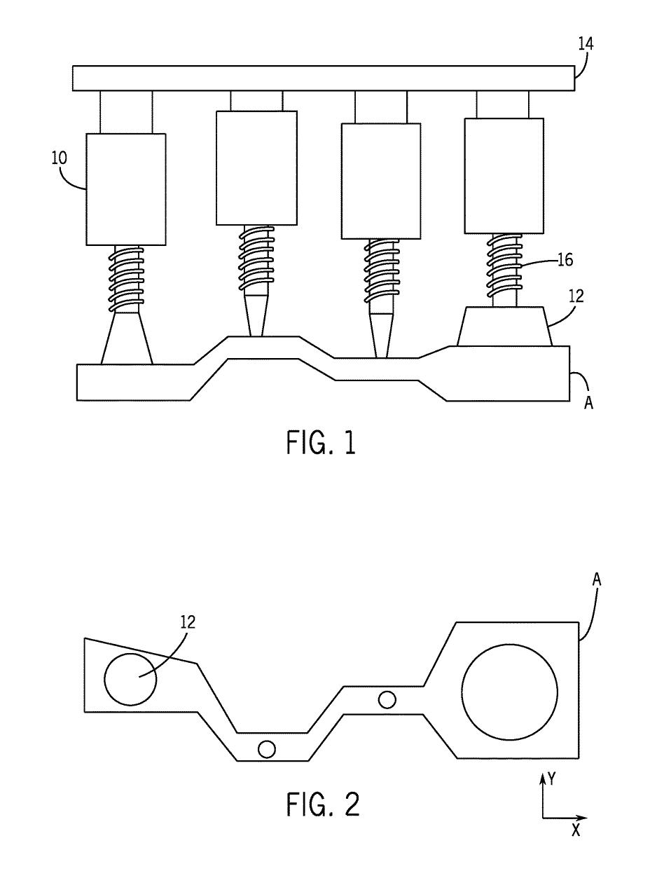

A three-dimensional (3D) staggered PnP multi head design, according to the first embodiment, uses multiple PnP heads that are staggered in all three dimensions using an array of rails/cams to optimize the pick positions on an irregular shaped object. An example of a four nozzle staggered configuration is shown in FIG. 1. The positions of the vacuum nozzles 10 are optimized by staggering them in two axes (x, y) as per the shape of the component A to be picked. Additionally the size and material of the nozzles may be varied to allow maximum pickup strength and low leakage during pick up. Thereafter the z axis (vertical) is adjusted by a screw or a lock mechanism on the shanks of the pickup head (not shown in FIG. 1). This combination of multiple nozzles is convenient yet effective, allowing easy adjustments and flexibility in some embodiments.

In this way, a traditional multiple PnP head system (using vacuum buildup and flexible nozzles) is transformed by adding a 3D staggering capability for the nozzles to achieve the contour of the component A to be picked as seen in FIG. 2.

Thus as shown in FIG. 1, each of the nozzles 10 includes a trapezoidal pickup head 12. But the trapezoidal pickup heads may be differently sized to provide different areas of suction contact with the odd-shaped object A to be picked up. For example, the area of the opening of the pickup heads 12 may be varied to accommodate for the amount of space located at a juxtaposed portion of the odd-shaped object A to be picked up. Thus, because of the shape of the object A, each of the pickup heads 12 may be a different distance from the gang head 14, again to accommodate for the vertical orientation of the odd-shaped object to be picked. Springs 16 may be used to resiliently bias the pickup heads 12 towards the object A.

As shown in FIG. 2, the various pickup heads 12 may be positioned at different locations spaced in both x and y dimensions based on the shape in x and y dimensions of the object A to be picked. In addition, as shown, the variable diameters of the openings of the pickup heads 12 accommodate for the xy shape of the object A as it is juxtaposed beneath the pickup head. Generally, the more available room, the larger the contact area, between the pickup head 12 and the object 12 to be picked, to increase the holding force, to the greatest possible extent consistent with the local shape of the object A to be picked.

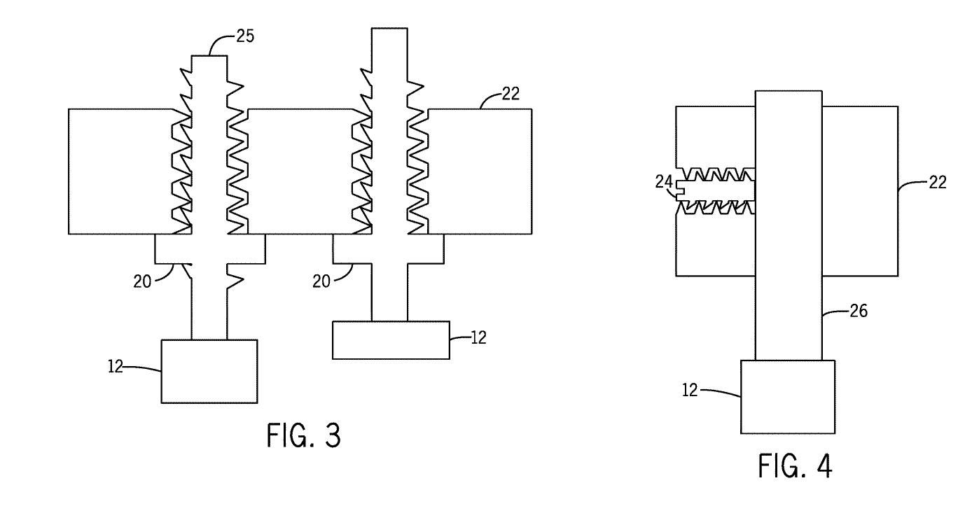

FIGS. 3 and 4 depict two techniques that can be used to adjust and lock the vertical (z) height of the individual pickup heads. FIG. 3 shows a screw-like mechanism to adjust z height and a locking mechanism using a threaded nut 20 that threads along a threaded shank 25 connected to pickup head 12 (shown as a simple rectangular box in this embodiment) that threads within a threaded rail 22.

The height or extension of the pickup head can be easily adjusted by rotating the nut 20 to move the shank 25 up and down relative to the nut 20. The shank 25 may include a vertical vacuum passage (not shown) to communicate to a vacuum source to the pickup head.

FIG. 4 shows an alternative approach in which a set screw 24 can be used to lock the z position of the shank 26 and pickup head 12 by pinching the shank 26 of the pickup head 12 against the walls of the rail 22.

Multiple other approaches in addition to those described above can be used to adjust the z height. The key here is the ability to stagger individual z heights of each pickup head 12 by any approach suitable to the design of the sub-assembly of the pick and place mechanism.

A self-learning PnP matrix, according to the second embodiment, utilizes an array of fixed-size nozzles to pick up a part. One advantage of some embodiments is that they can be used to pick up different objects without changing the nozzles, making it a universal pick-and-place head. Whenever there is a new part to be picked, the nozzles are brought down till they touch the part. Depending on the 3D shape of the part, some nozzles touch the part and some do not. Even the ones that touch the part may do so at different heights. Then the nozzles are locked in place and the pick and place head is ready for use. This self-learning ability to automatically figure out the individual nozzle height adjustments is an added advantage of some embodiments of the matrix design.

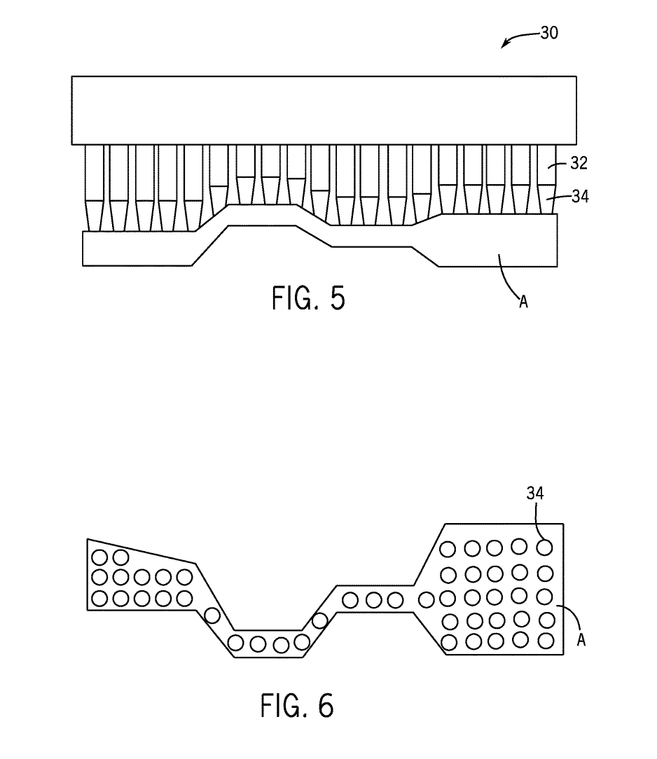

FIGS. 5 and 6 show an example of a nozzle matrix picking up an odd-shaped object. In this example, the matrix is made up of rows of regularly spaced pickup heads and perpendicular columns of regularly spaced pickup heads.

In FIG. 5, a pick and place rail 30 includes a plurality of downwardly depending nozzles 32 with frustoconical pickup heads 34 in contact with an odd-shaped object A to be picked. The nozzles 32 have different vertical extents from the rail 30 to adjust for the height of the local portions of the object A to be picked.

As shown in FIG. 6, in one embodiment, all the pickup heads 34 have the same contact area. However, they are dispersed along the length and width of the object A to be picked in a regular matrix array in x and y directions. Thus, each region of the object A to be picked contacts a number of pickup heads corresponding to the available contact area on the object A.

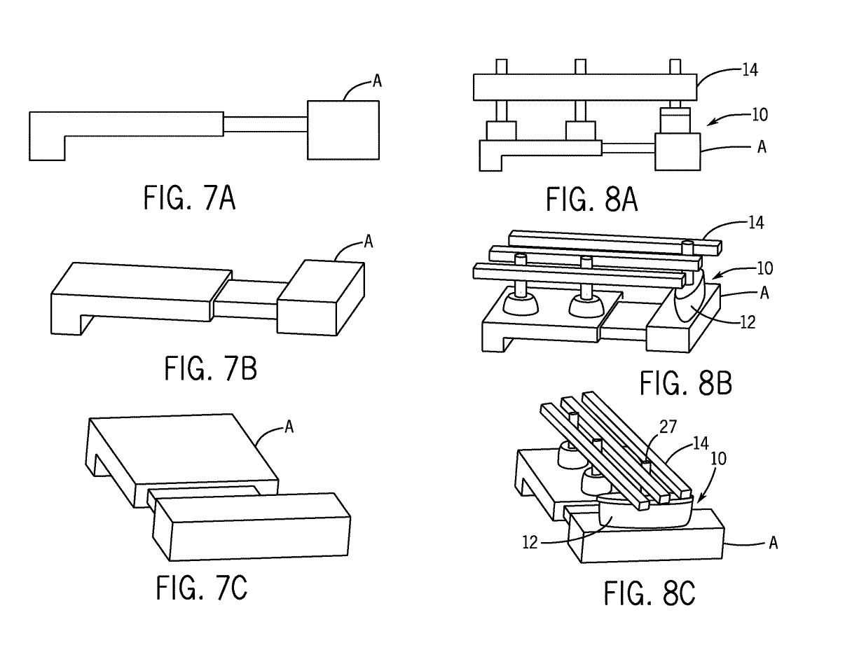

FIGS. 7A, 7B, and 7C show a typical component A to be picked in three different views. Specifically, the component is shown in a front view in FIG. 7A, a tilted view in FIG. 7B, and a side view in FIG. 7C. Corresponding views of the pickup mechanism with respect to the component are shown in FIGS. 8A, 8B, and 8C. For example in FIG. 8A, the front view, a component A is contacted by three nozzles 10 that slide vertically within a rail or cam 14. Thus, each of the nozzles has a different vertical extent because of the local configuration of the component A.

As better shown in FIG. 8B, a plurality of parallel rails or cams 14 may be used in some embodiments. Nozzles 10 may be positioned at different locations along the length of each rail to define a two-dimensional array of nozzles. This is also shown in FIG. 8C. Then the vertical upward or downward extent of each nozzle is adjusted so that its pickup head 12 contacts the component A given its local height. In this embodiment the pickup heads 12 are of different shapes and sizes to increase the force applied given the available contact area on the component A. In one embodiment each nozzle 10 includes a shank 27 that is adjustably held between two adjacent rails 14.

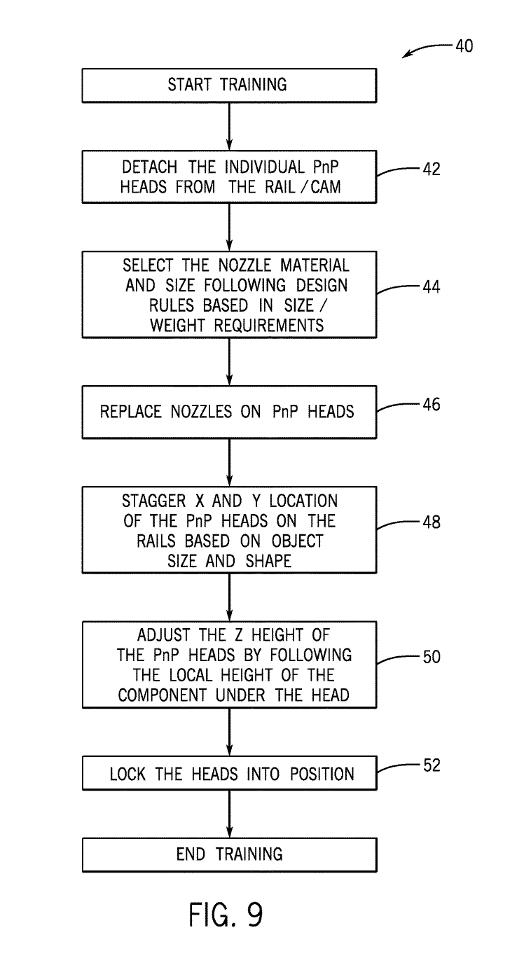

FIG. 9 shows a sequence for training 3D staggered PnP multi-head design (FIGS. 8A-8C). The training sequence 40 begins by detaching the independent PnP nozzles from the rail/cam as indicated in block 42. Then the pickup head 12 material and size is selected following design rules based on size and weight requirements as indicated in block 44. Next, the pickup heads 12 are replaced as indicated in block 46. They can be reattached to the shanks 27 or a unitary shank and pickup head may be replaced, to mention two examples.

The x and y locations for the PnP pickup heads are staggered in the x and y dimensions on rails based on the object size and shape as indicated in block 48. Then in block 50, the height of the PnP heads is adjusted by following the local height of the component under the head. Finally, the heads are locked in position as indicated in block 52.

One method to enable an automatically vertical adjustable gang picking matrix is to use a nozzle array that is similar to the children's pin art or bed of nails toy. The nozzle matrix comes down conform to the surface of the part and then picks up the components utilizing multiple vacuum nozzles. The matrix then moves to the final location and places the part, turning off the vacuum.

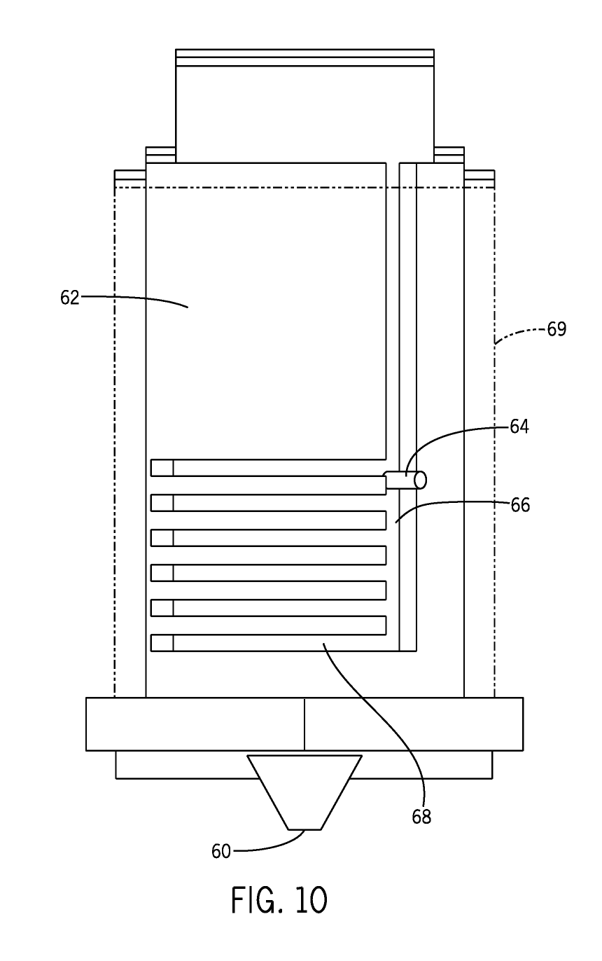

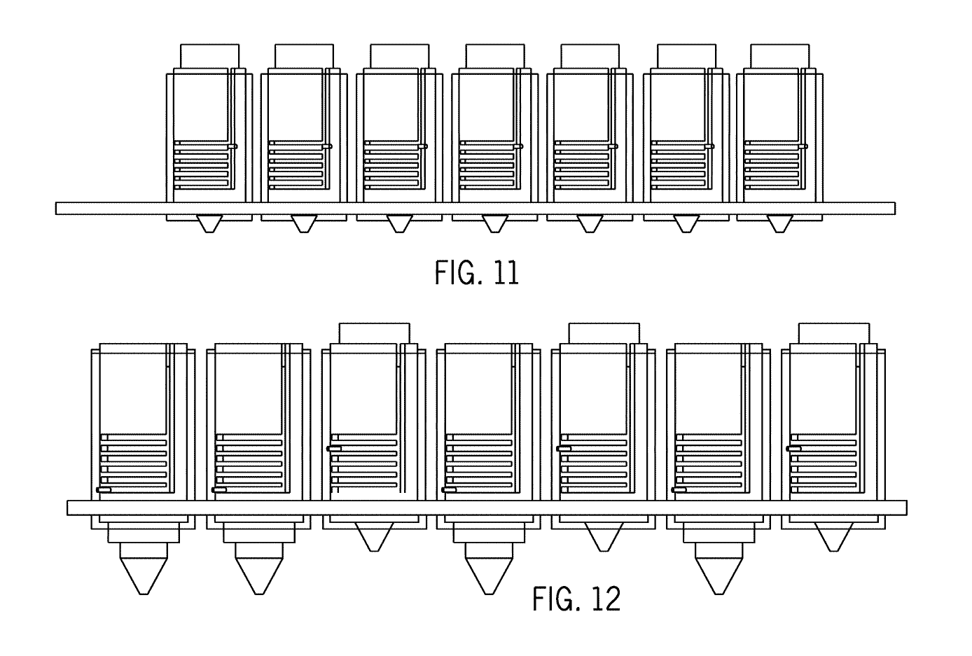

One design to enable such a method is shown in FIG. 10. The pickup head 60 is fitted into a vertically adjustable outer housing 69 which has graduated locking features or slots 66 that lock the nozzle vertically into place at an adjustable height. The nozzle includes a concentric telescoping outer housing 69 with pin 64 that rides in the slot 66 in the inner housing 62. During a teaching step, the nozzle 60 slides up and down as the pin 64 rides in the vertical portion of the slot 66 of the inner housing.

The matrix slides down over the part and when the first nozzles run out of vertical travel, a cam mechanism gang locks all the nozzles into place. This causes the outer housing 69 to rotate which forces the sliding mechanism or pin 64 into one of the graduated horizontal slots 68. This locks each nozzle vertically in place.

FIGS. 11-13 illustrate the above scenarios, with nozzles at a variety of vertical extensions so as to automatically adjust to the local vertical height of the component to be picked. FIG. 11 shows the initial nozzle orientation. FIG. 12 shows the vertically adjusted orientations.

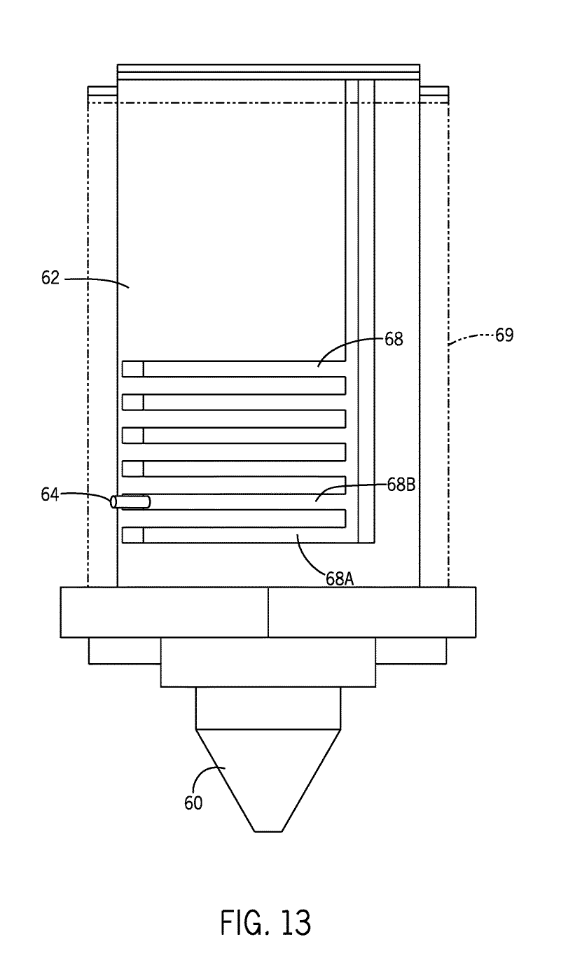

FIG. 13 shows a depiction of the outer and inner housings, with the outer housing cutaway but leaving the pin 64 visible. In this case, the pin 64 is in a different position, namely in a horizontal slot 68B, to lock the nozzle 60 at a particular vertical height. To assume this position, one or the other of the inner or outer housing 62 and 69 moves relative to the other housing. That is, the outer housing can be moved down from the position shown in FIG. 10 and rotated to the left to ride into the horizontal slot 68B. Conversely, the outer housing may be fixed and the inner housing may move upwardly so that the pin slides down the vertical extent of the slot 66 and then it rotates to the right to cause the pin 64 to enter and extend across the horizontal slot 68B to the position shown in FIG. 13. In either case, the vertical height may be adjusted by automated mechanisms which drive each nozzle to be locked at its current position. In some cases, a large number of horizontal slots may be provided for a very fine vertical adjustment. In other cases, the nozzle may be provided with some play by simply increasing the vertical extent of the horizontal slots.

Once the nozzles are locked into position, the nozzle has been trained to the component shape. Each nozzle will have some local compliance in it to handle tolerances in the shape of the part to be handled. With the nozzle locked into position, the system can begin picking and placing components. Once completed, the nozzle can be unlocked and repeated for the next part type.

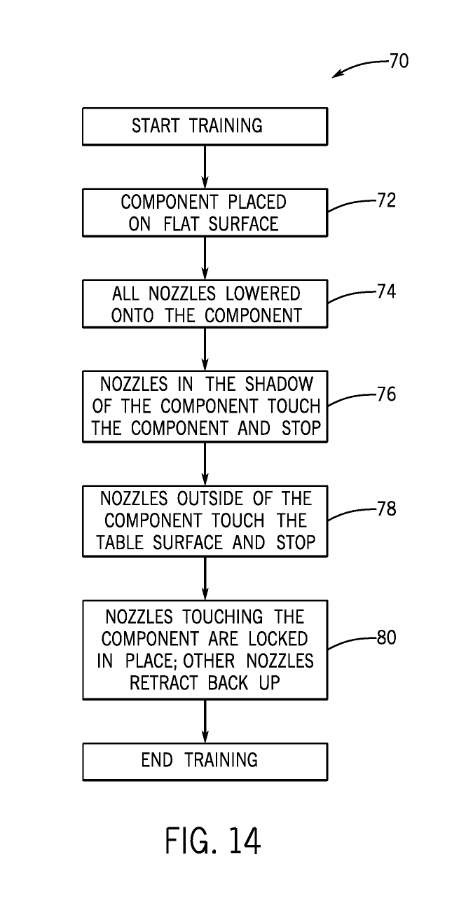

FIG. 14 shows a sequence involved in training the self-learning PnP head design prior to picking an object. The sequence shown in FIG. 14 begins by placing the component to be picked on a flat surface as indicated in block 72. Then the nozzles are lowered onto the component as indicated in block 74. Nozzles in the shadow of the component touch the component and stop as indicated in block 76. Nozzles outside the shadow of the component touch the flat surface and stop as indicated in block 78. Nozzles touching the component are locked in place while the other nozzles are retracted back up as indicated in block 80.

These systems are able to use multiple nozzles of different shapes, sizes, and even materials depending on the application. Although each individual nozzle behaves similar to what an existing single head PnP design would do. The three-dimensional position flexibility of the staggered design and the auto nozzle selection and height adjustment capability of the matrix design makes them suitable to pick objects of almost any size and shape. Additionally these designs can be easily incorporated in a typical semiconductor manufacturing equipment as they are extensions of current systems.

Universal pick and place of components with various shapes, sizes, and compositions may be made from and onto a whole range of packaging architectures such as wearable packaging, curved surface packaging, and flexible packaging, etc.

The following clauses and/or examples pertain to further embodiments:

One example embodiment may be a pick and place mechanism comprising a plurality of vacuum nozzles, a frame to mount said nozzles over a component to enable the nozzles to be variably positioned in three dimensions. The mechanism may include wherein said nozzles include differently sized pickup heads. The mechanism may include wherein said nozzles are lockable at an adjustable height over said component. The mechanism may include said nozzles to be locked at different heights above said component. The mechanism may include a slotted cam on each nozzle to adjust the height of each nozzle over said component. The mechanism may include said frame including a plurality of parallel rails to mount said nozzles. The mechanism may include said nozzles slidably positionable along said rails. The mechanism may include said nozzles being vertically adjustable relative to said component. The mechanism may include said nozzles that contact said component being locked. The mechanism may include said nozzles that do not contact said component being retracted. The mechanism may include a regular matrix of nozzles including rows and columns of regularly spaced nozzles.

In another example embodiment may be a method comprising mounting pick and place mechanism nozzles on a frame over a component so that said nozzles may be variably positioned in three dimensions, lowering the nozzles onto the component to be picked, and allowing said nozzles to automatically accommodate for the vertical height of the component. The method may include mounting differently sized pickup heads on said frame. The method may include locking said nozzles at an adjustable height over said component. The method may include locking said nozzles at different heights above said component. The method may include using a slotted cam on each nozzle to adjust the height of each nozzle over said component. The method may include providing a plurality of parallel rails to mount said nozzles. The method may include mounting said nozzle to be slidably positionable along said rails. The method may include mounting said nozzles to be vertically adjustable relative to said component. The method may include locking nozzles that contact said component. The method may include retracting nozzles that do not contact said component. The method may include using a regular matrix of nozzles including rows and columns of nozzles.

References throughout this specification to “one embodiment” or “an embodiment” mean that a particular feature, structure, or characteristic described in connection with the embodiment is included in at least one implementation encompassed within the present disclosure. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While a limited number of embodiments have been described, those skilled in the art will appreciate numerous modifications and variations therefrom. It is intended that the appended claims cover all such modifications and variations as fall within the true spirit and scope of this disclosure.

What is claimed is:

1. A pick and place mechanism comprising:
a plurality of vacuum nozzles;
a frame to mount said nozzles over a component to enable the nozzles to be variably positioned in three dimensions.

2. The mechanism of claim 1 wherein said nozzles include differently sized pickup heads.

3. The mechanism of claim 1 wherein said nozzles are lockable at an adjustable height over said component.

4. The mechanism of claim 3, said nozzles to be locked at different heights above said component.

5. The mechanism of claim 4 including a slotted cam on each nozzle to adjust the height of each nozzle over said component.

6. The mechanism of claim 1, said frame including a plurality of parallel rails to mount said nozzles.

7. The mechanism of claim 6, said nozzles slidably positionable along said rails.

8. The mechanism of claim 1 including said nozzles being vertically adjustable relative to said component.

9. The mechanism of claim 8, said nozzles that contact said component being locked.

10. The mechanism of claim 8, said nozzles that do not contact said component being retracted.

11. The mechanism of claim 1 including a regular matrix of nozzles including rows and columns of regularly spaced nozzles.

12. A method comprising:
mounting pick and place mechanism nozzles on a frame over a component so that said nozzles may be variably positioned in three dimensions;
lowering the nozzles onto the component to be picked; and
allowing said nozzles to automatically accommodate for the vertical height of the component.

13. The method of claim 12 including mounting differently sized pickup heads on said frame.

14. The method of claim 12 including locking said nozzles at an adjustable height over said component.

15. The method of claim 14 including locking said nozzles at different heights above said component.

16. The method of claim 15 including using a slotted cam on each nozzle to adjust the height of each nozzle over said component.

17. The method of claim 12 including providing a plurality of parallel rails to mount said nozzles.

18. The method of claim 17 including mounting said nozzle to be slidably positionable along said rails.

19. The method of claim 12 including mounting said nozzles to be vertically adjustable relative to said component.

20. The method of claim 19 including locking nozzles that contact said component.

21. The method of claim 19 including retracting nozzles that do not contact said component.

22. The method of claim 12 using a regular matrix of nozzles including rows and columns of nozzles.
